(19) United States
(12) Patent Application Publication
(10) Pub. No.: US 2025/0121733 A1
(43) Pub. Date: Apr. 17, 2025

(54) ELECTRIFIED VEHICLE AND POWER SOURCE MANAGEMENT METHOD FOR THE SAME

(71) Applicants: Hyundai Motor Company, Seoul (KR); Kia Corporation, Seoul (KR)

(72) Inventor: Jung Hyun Lee, Hwaseong (KR)

(21) Appl. No.: 18/984,337

(22) Filed: Dec. 17, 2024

Related U.S. Application Data
(63) Continuation of application No. 17/851,259, filed on Jun. 28, 2022.

(30) Foreign Application Priority Data
Dec. 31, 2021 (KR) 10-2021-0194633

(51) Int. Cl. B60L 58/12; B60L 53/20; B60L 53/80; H02J 7/00; H02J 7/34

(52) U.S. Cl. CPC B60L 58/12; B60L 53/20; B60L 53/80; H02J 7/00032; H02J 7/0013; H02J 7/005; H02J 7/00712; H02J 7/007194; H02J 7/342; H02J 2207/20

(57) ABSTRACT

An electrified vehicle may be additionally equipped with a swappable battery, and a power source management method for the same. The electrified vehicle includes a driving power unit including a motor and an inverter, a main battery unit electrically connected to the driving power unit, the main battery unit including a first battery and a first BMS for controlling the first battery, the main battery unit being fixedly disposed in the electrified vehicle, and a DC converter electrically connected to the main battery unit, the DC converter including a connector, in which, when a swappable battery unit including a second battery and a second BMS for controlling the second battery may be connected to the connector, the first BMS acquires second battery information output by the second BMS.

This application claims under 35 U.S.C. § 119 (a) the benefit of Korean Patent Application No. 10-2021-0194633, filed on Dec. 31, 2021, which may be hereby incorporated by reference as if fully set forth herein.

### BACKGROUND OF THE DISCLOSURE

### Field of the Disclosure

The present disclosure relates to an electrified vehicle that may be additionally equipped with a swappable battery, and a power source management method for the same. The term “electrified vehicle” refers to a range of technologies that use electricity to propel a vehicle.

### Discussion of the Related Art

Recently, with the increase in interest in the environment, the number of electrified vehicles each having an electric motor as a source of driving force has been increasing.

A significant number of users of electrified vehicles have a short-distance urban driving pattern. However, in an electrified vehicle, the charging time of a battery may be relatively long compared to the refilling time of fuel in an internal combustion engine vehicle. Thus, with electric vehicles (EV), the maximum travel distance on a single battery-full charge, so called EV mileage, may be important.

The EV mileage may be increased by increasing the size (i.e. the capacity) of the battery, however the weight of the vehicle may be increased too, and the vehicle price may be greatly increased since the battery price accounts for a large proportion in an electrified vehicle.

In order to solve the problems of reduced travel distance range due to battery deterioration and the long charging time, some manufacturers considers making the battery detachable and thus replacing it with a new or fully charged one. In the case of a small vehicle such as an electric scooter, a low-voltage/low-capacity battery may be applied and a user may directly exchange the battery. However, a large-capacity battery for vehicles may be difficult to self-replace due to weight and safety issues, and thus a dedicated infrastructure may be required. However, it may be necessary to ensure a site and replacement equipment at a high cost to expand the infrastructure for battery replacement, and even when the infrastructure may be in place, there may be a problem that driving becomes difficult when there may be physical damage to or burnout of a connection part as the number of replacements may be accumulated.

### SUMMARY OF THE DISCLOSURE

Accordingly, the present disclosure may be directed to an electrified vehicle and a power source management method for the same that substantially obviate one or more problems due to limitations and disadvantages of the related art.

An object of the present disclosure may be to provide an electrified vehicle that may be additionally equipped with a swappable battery, and a power source management method for the same.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, an electrified vehicle includes a driving power unit including a motor and an inverter, a main battery unit electrically connected to the driving power unit, the main battery unit including a first battery and a first battery management system (BMS) for controlling the first battery, the main battery unit being fixedly disposed in the electrified vehicle, and a DC converter electrically connected to the main battery unit, the DC converter including a connector, the DC converter being configured to boost charging power input through the connector and transfer the boosted charging power to the main battery unit, in which, when a swappable battery unit including a second battery and a second BMS for controlling the second battery may be connected to the connector, the first BMS acquires battery information on the second battery output by the second BMS.

The first BMS may be configured to acquire and may acquire the second battery information via the DC converter.

The first BMS may be configured to determine and may determine total available energy based on the second battery information and battery information on the first battery.

The second battery information may include cell type information and rated capacity information, and the first BMS may be configured to estimate and may estimate a state of charge (SOC) of the second battery based on a voltage of the second battery in a no-load state, and a state of health (SOH) of the second battery based on a result measured by applying a test current.

The first BMS may be configured to estimate and may estimate the SOC based on an open circuit voltage table for each cell type, and may be configured to estimate and may estimate the SOH based on an internal resistance table for each cell type.

The electrified vehicle may further include a vehicle control unit configured to determine whether to perform first charging control for charging the first battery with energy of the second battery based on the first battery information and the second battery information.

When the first battery may be in a chargeable state and the second battery may be in a dischargeable state, the vehicle control unit may be configured to determine to perform the first charging control, and may perform the first charging control.

The vehicle control unit may be configured to forward and may forward a charging command to the first BMS upon determining to perform the first charging control, and the first BMS may be configured to forward and may forward the charging command to the second BMS.

The second BMS may be configured to control a charging current or charging power based on a temperature of the second battery in response to start of the first charging control.

The swappable battery unit may further include a cooling fan, and the second BMS may be configured to control an operation of the cooling fan based on a vehicle speed and a temperature of the second battery in response to start of the first charging control.

When an SOC of the first battery reaches a target SOC after determining to perform the first charging control, the vehicle control unit may be configured to suspend and may suspend the first charging control.

When a total path may be longer than a total remaining distance range determined based on available energy of the first battery and available energy of the second battery, the target SOC may include an SOC with which a charging reservation point or a chargeable point may be able to be reached.

The electrified vehicle may further include a braking controller configured to determine a hydraulic braking amount and a regenerative braking amount when the vehicle control unit determines a total required braking amount, in which the vehicle control unit may determine whether to perform second charging control for charging the second battery with energy of the first battery in controlling regenerative braking according to the determined regenerative braking amount.

When the first battery may be in a non-chargeable state and the second battery may be in a chargeable state, the vehicle control unit may be configured to determine to perform the second charging control, and may perform the second charging control.

The vehicle control unit may be configured to compare and may compare regenerative energy loss due to a non-chargeable state of the first battery with path loss resulting from charging the second battery with energy of the first battery, and be configured to perform and may perform the second charging control until an SOC of the first battery reaches a target SOC when the path loss may be small.

The first BMS may be configured to monitor and may monitor a regenerative braking execution amount by the regenerative braking as the second charging control may be performed, and may be configured to perform and may perform a control operation so that the second battery may be charged by the execution amount.

In another embodiment of the present disclosure, a power source management method for an electrified vehicle including a main battery unit, which includes a first battery and a first BMS for controlling the first battery and may be fixedly disposed, includes connecting a swappable battery unit including a second battery and a second BMS for controlling the second battery to a connector of a DC converter electrically connected to the main battery unit, outputting, by the second BMS, battery information on the second battery, acquiring, by the first BMS, the second battery information via the DC converter, and determining, by the first BMS, total available energy based on battery information on the first battery and the acquired second battery information.

In another embodiment of the present disclosure, an electrified vehicle includes a driving power unit including a motor and an inverter, a main battery unit electrically connected to the driving power unit, the main battery unit including a first battery and a first BMS for controlling the first battery, the main battery unit being fixedly disposed in the electrified vehicle, a DC converter electrically connected to the driving power unit, the DC converter including a connector, a secondary battery unit including a second battery and a second BMS configured to control the second battery, a secondary battery mounting part configured to provide a space for accommodating the secondary battery unit which is accessible from outside by a driver, the connector exposed in the space and the secondary battery unit detachably mounted in the space and electrically connected to the connector, in which, when the secondary battery unit is connected to the connector, the first BMS acquires battery information on the second battery output by the second BMS.

It may be to be understood that both the foregoing general description and the following detailed description of the present disclosure may be exemplary and explanatory and may be intended to provide further explanation of the disclosure as claimed.

### BRIEF DESCRIPTION OF THE DRAWINGS

The accompanying drawings, which may be included to provide a further understanding of the disclosure and may be incorporated in and constitute a part of this application, illustrate embodiment(s) of the disclosure and together with the description serve to explain the principle of the disclosure. In the drawings:

FIG. 1 is a block diagram illustrating an example of an electrified vehicle equipped with a swappable battery according to an embodiment of the present disclosure;

FIG. 2 is a flowchart illustrating an example of a power source management method for the electrified vehicle according to an embodiment of the present disclosure;

FIG. 3 is a flowchart illustrating an example of a process of estimating a state of a second battery of a swappable battery unit according to an embodiment of the present disclosure;

FIG. 4 is a flowchart illustrating an example of a power source management method during regenerative braking of the electrified vehicle according to an embodiment of the present disclosure; and

FIG. 5 is a block diagram illustrating an example of an electrified vehicle equipped with a swappable battery according to another embodiment of the present disclosure.

FIG. 6 is a conceptual structural drawing for showing three exemplary embodiments of a secondary battery mounting unit.

### DETAILED DESCRIPTION OF THE DISCLOSURE

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. These terms are merely intended to distinguish one component from another component, and the terms do not limit the nature, sequence or order of the constituent components. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Throughout the specification, unless explicitly described to the contrary, the word “comprise” and variations such as “comprises” or “comprising” will be understood to imply the inclusion of stated elements but not the exclusion of any other elements. In addition, the terms “unit”, “-er”, “-or”, and “module” described in the specification mean units for processing at least one function and operation, and can be implemented by hardware components or software components and combinations thereof.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor and is specifically programmed to execute the processes described herein. The memory is configured to store the modules and the processor is specifically configured to execute said modules to perform one or more processes which are described further below.

Further, the control logic of the present disclosure may be embodied as non-transitory computer readable media on a computer readable medium containing executable program instructions executed by a processor, controller or the like. Examples of computer readable media include, but are not limited to, ROM, RAM, compact disc (CD)-ROMs, magnetic tapes, floppy disks, flash drives, smart cards and optical data storage devices. The computer readable medium can also be distributed in network coupled computer systems so that the computer readable media is stored and executed in a distributed fashion, e.g., by a telematics server or a Controller Area Network (CAN).

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Hereinafter, embodiments of the present disclosure will be described in detail with reference to the accompanying drawings, and the same or similar elements will be given the same reference numerals regardless of reference symbols, and redundant description thereof will be omitted. In the following description, the terms “module” and “unit” for referring to elements may be assigned and used interchangeably in consideration of convenience of explanation, and thus, the terms per se do not necessarily have different meanings or functions. Further, in describing the embodiments disclosed in the present specification, when it may be determined that a detailed description of related publicly known technology may obscure the gist of the embodiments disclosed in the present specification, the detailed description thereof will be omitted. The accompanying drawings may be used to help easily explain various technical features and it should be understood that the embodiments presented herein may not be limited by the accompanying drawings. As such, the present disclosure should be construed to extend to any alterations, equivalents and substitutes in addition to those which may be particularly set out in the accompanying drawings.

Although terms including ordinal numbers, such as “first”, “second”, etc., may be used herein to describe various elements, the elements may not be limited by these terms. These terms may be generally used to distinguish one element from another.

When an element may be referred to as being “coupled” or “connected” to another element, the element may be directly coupled or connected to the other element. However, it should be understood that another element may be present therebetween. In contrast, when an element may be referred to as being “directly coupled” or “directly connected” to another element, it should be understood that there may be no other elements therebetween.

A singular expression includes the plural form unless the context clearly dictates otherwise.

In the present specification, it should be understood that a term such as “include” or “have” may be intended to designate that the features, numbers, steps, operations, elements, parts, or combinations thereof described in the specification may be present, and does not preclude the possibility of addition or presence of one or more other features, numbers, steps, operations, elements, parts, or combinations thereof.

In addition, the term “unit” or “control unit” included in the names of a hybrid control unit (HCU), a vehicle control unit (VCU), etc. may be merely a widely used term for naming a controller that controls a specific vehicle function, and does not mean a generic functional unit. For example, each controller may include a communication device that communicates with another controller or a sensor to control a function assigned thereto, a memory that stores an operating system, a logic command, input/output information, etc., and one or more processors that perform determination, calculation, decision, etc. necessary for controlling a function assigned thereto. Although a control unit may be described with respect to its function, for example the HCU or VCU, the control units are not necessarily separate units but may be integrated into a single unit or separated into a plurality of units. Different functional controllers may therefore be integrated into a single controller and still meet the recitations of the different functional controllers.

An embodiment of the present disclosure proposes that a secondary swappable battery (referred to as ‘swappable battery’ hereinafter in this description) be additionally connected to an electrified vehicle together with a main battery electrically connected to a driving motor, so that power of the main battery and power of the swappable battery may be comprehensively managed.

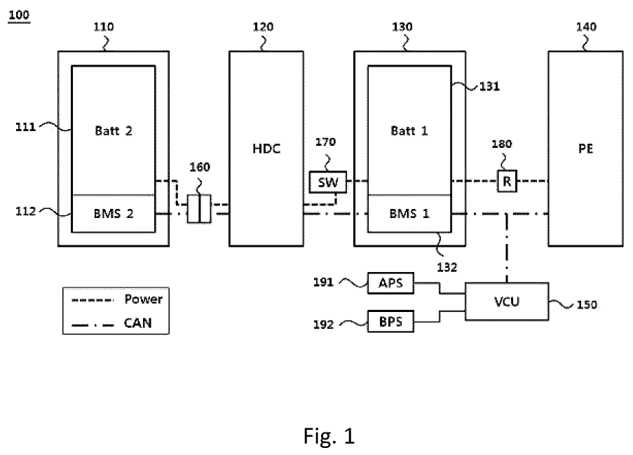

First, a configuration of the electrified vehicle according to an embodiment will be described with reference to FIG. 1.

FIG. 1 is a block diagram illustrating an example of the electrified vehicle equipped with the swappable battery according to the embodiment of the present disclosure.

Referring to FIG. 1, the electrified vehicle 100 according to the embodiment may include a swappable battery unit 110, a DC converter 120, a main battery unit 130, a driving power unit (PE: Power Electric) 140, a VCU 150, a connector 160, a switch 170, a main relay 180, and pedal sensors 191 and 191.

FIG. 1 mainly illustrates elements related to the present embodiment, and it may be obvious that fewer or more elements may be included in the actual implementation of the vehicle.

Hereinafter, each element will be described.

The swappable battery unit 110 may include a second battery 111 and a second BMS 112. The second BMS 112 manages a voltage, a current, a temperature, an SOC, an SOH, etc. of the second battery 111, and may be configured to control charging/discharging of the second battery 111. In addition, the second BMS 112 may be configured to set and manage upper and lower limits for the SOC of the second battery 111, and may be configured to store cell type information, rated capacity information, etc. of the second battery 111. Further, the second BMS 112 may be configured to transmit information on the second battery 111 to the outside (that is, the DC converter 120) through a predetermined vehicle communication protocol (for example, controller area network (CAN)), and receive a command for charging/discharging of the second battery 111. Merely for the sake of convenience in describing, in the following description, it may be assumed that the vehicle communication protocol is CAN communication. However, it may be apparent to those skilled in the art that the protocol may be substituted with other protocols such as CAN-FD (Flexible Data-rate) and Ethernet.

Although not illustrated in FIG. 1, the swappable battery unit 110 may be provided with a cooling device for cooling the second battery 111, for example, an air cooling fan. In this case, the second BMS 112 may be configured to control an operating state of the fan in consideration of the state of the second battery 111, the vehicle speed, etc. The swappable battery unit 110 may be implemented using a natural cooling scheme, or may be cooled using water cooling by disposing a cooling pad through which coolant circulates in a portion of the vehicle in which the swappable battery unit 110 may be mounted.

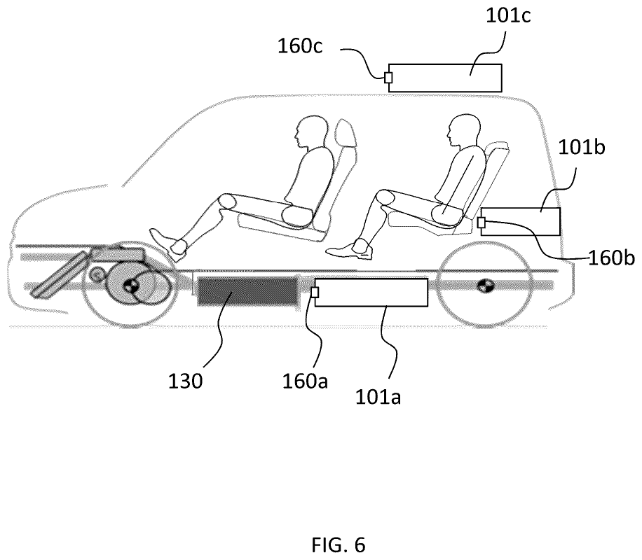

Meanwhile, as shown in FIG. 6, the vehicle may comprise a battery mounting part 101a, 101b, 101c in which the connector 160a, 160b, 160c may be exposed and the swappable battery unit 110 may be detachably mounted. The battery mounting part 101a, 101b, 101c, as shown in FIG. 6, may be located on a roof of the electrified vehicle, or in a trunk or a space under the vehicle. In another embodiment, the swappable battery may be connected to the vehicle in the form of a trailer provided with separate wheels. These are only examples, and the present disclosure may not be limited thereto. The battery mounting part may be configured such that the battery accommodating space is easily accessed by a driver and the swappable battery unit may be easily mounted on and detached from the battery mounting part so that the driver can install and remove the swappable battery unit 110 without difficulties. Also, the battery mounting part may comprise a fastening structure which fastens the swappable battery unit 110 firmly but can be released by an easy work.

The swappable battery unit 110 may be connected to the DC converter 120 through the connector 160. Here, being connected may mean that a high-voltage power cable and a CAN communication line may be respectively connected. In addition, the DC converter 120 may be connected to the main battery unit 130. That is, the swappable battery unit 110 may exchange power or communicate with the main battery unit 130 via the DC converter 120.

The DC converter 120 may be a high DC-DC converter (HDC). A reason therefor may be to boost a voltage of the second battery 111 and transfer the voltage to a first battery 131 side on the assumption that the second battery 111 of the swappable battery unit 110 may be smaller than the first battery 131 of the main battery unit 130, that is, has a low voltage/low capacity. In addition, the DC converter 120 may be configured to relay communication between the second BMS 112 of the swappable battery unit 110 and a first BMS 132 of the main battery unit 130.

Depending on the implementation, when the voltage of the first battery 131 and the voltage of the second battery 111 may be the same, the DC converter 120 may be omitted, and when the voltage of the second battery 111 may be higher than the voltage of the first battery 131, a low DC-DC converter (LDC) type may be adopted.

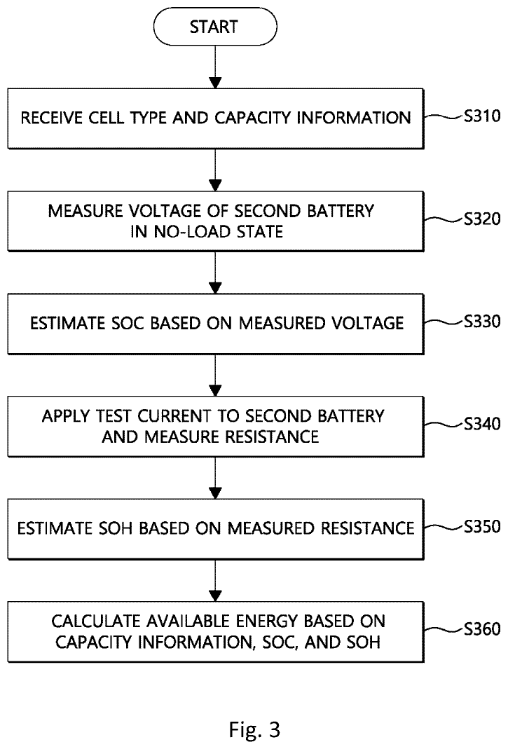

The main battery unit 130 may include the first battery 131 and the first BMS 132 as illustrated in the figure, and may be preferably permanently fixed to the vehicle. When the start button or ignition key may be turned on (for example, IG On, EV Ready, etc.), the first BMS 132 may acquire state information of the second battery 111, which may be forwarded to the DC converter 120 by the second BMS 112, from the DC converter 120, and determine the sum total energy of the first battery 131 and the second battery 111 based on the state information. When the second BMS 112 does not provide SOC or SOH information and only provides cell type information and rated capacity information, the first BMS 132 may estimate the SOC and the SOH of the second battery 111 based on the provided information, which will be described later with reference to FIG. 3.

In addition, upon receiving a charging command from the VCU 150, the first BMS 132 may forward the charging command to the second BMS 112 via the DC converter 120 so that the first battery 131 may be charged with power of the second battery 111. Depending on the case, it may be possible to perform a control operation so that the second battery 111 may be charged with power of the first battery 131.

The main battery unit 130 may be connected to a driving power unit 140, and the driving power unit 140 may include a motor and an inverter (not illustrated).

The VCU 150 may be configured to determine a required driving force in consideration of an accelerator pedal position sensor (APS) value of an APS 191, and determine a required braking force in consideration of a brake pedal position sensor (BPS) value of a BPS 192. The VCU 150 may be configured to determine the driving torque or regenerative braking torque to be output by the motor of the driving power unit 140 in consideration of the required driving force or the required braking force, and forward a resultant torque command to a motor controller (not illustrated) or an inverter (not illustrated). In addition, the VCU 150 may be configured to forward a charging or discharging command for the first battery 131 to the first BMS 132 in consideration of the driving situation or the state of the first battery 131.

Further, the VCU 150 may be configured to comprehensively manage energy of the first battery 131 and the second battery 111 based on state information of each of the first battery 131 and the second battery 111 or total available energy information received from the first BMS 132.

Here, in comprehensive energy management of the first battery 131 and the second battery 111, it may be necessary to perform control in consideration of characteristics of the second battery 111, which may be a swappable battery. A reason therefor may be that, while control may be easy in a general high-voltage battery system since a main battery including cells having the same cell type and SOH may be used, it may be highly likely that a voltage, a cell type, an SOH, etc. may be different from those of the main battery when the swappable battery may be connected.

Table 1 below shows examples of combinations of various main batteries and swappable batteries.

TABLE 1

| Case | Main battery | Swappable battery | Capacity | SOH | Others |
|---|---|---|---|---|---|
| 1 | NCM811 | NCM811(NCM811 + α mixed | 30 kWh | 100% | Same cell |
| | (800 V/73 kWh) | (high Nickel Li-ion battery | | | Different capacities, |
| | | | | | same SOH |
| 2 | | NCM811 | 32 kWh | 100% | Different cells |
| | | (Different mixing ratio compared | | | Different capacities, |
| | | to NE cell) | | | same SOH |
| 3 | | LFP (Iron Phosphate) | 20 kWh | 100% | Different cells |
| | | | | | Different capacities, |
| | | | | | same SOH |
| 4 | | NCM622 | 25 kWh | 70% | Different cells |
| | | (Apply reusable battery) | | | Different capacities, |
| | | | | | different SOHs |

In Table 1, NCM denotes a composition of a battery cathode material, which means nickel, cobalt, and manganese in this order, and three numbers after NCM indicate a component ratio in the decile. That is, the NCM811 battery may mean that a ratio of nickel:cobalt:manganese in the cathode material may be 8:1:1.

Referring to Table 1, various illustrative combinations may be shown in which at least one of a cell type, a capacity, or an SOH may be different between a main battery and a swappable battery.

As described above, the type or state of each battery may be different. Moreover, even when the total available energy may be the sum of SOCs of the first battery 131 and the second battery 111, since the motor of the driving power unit 140 may be supplied with power from the first battery 131, the power of the second battery 111 may not be converted into a distance range travelled by itself. Accordingly, the VCU 150 may manage the total remaining distance range separately from the total available energy in consideration of path loss (for example, second battery discharging efficiency, DC converter efficiency, first battery charging efficiency, etc.) in charging the first battery 131 with the power of the second battery 111 and battery characteristics (cell type, SOH, etc.). In this way, the electrified vehicle according to the present embodiment may provide more accurate total remaining distance range information to a driver.

Meanwhile, as illustrated in FIG. 1, the switch 170 may be disposed on a high-voltage power cable between the DC converter 120 and the main battery unit 130, and the main relay 180 may be provided on a high-voltage power cable between the main battery unit 130 and the driving power unit.

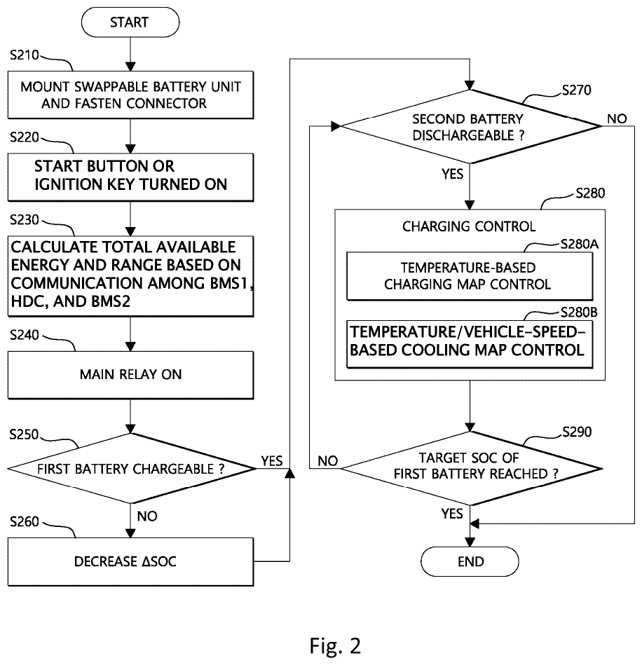

A power source management method for the electrified vehicle according to an embodiment will be described based on the above-described vehicle configuration with reference to FIG. 2.

FIG. 2 is a flowchart illustrating an example of the power source management method for the electrified vehicle according to the embodiment of the present disclosure.

Referring to FIG. 2, the swappable battery unit 110 may be mounted on the vehicle 100, and the connector 160 connected to the DC converter 120 may be fastened (that is, connected to a high-voltage power cable and a communication line) (S210).

When the start button or ignition key may be turned on after the swappable battery unit 110 may be connected (S220), a power source of the second BMS 112, the DC converter 120, and the first BMS 132 may be turned on to start communication, and the total available energy and the total remaining distance range may be calculated using information obtained through the communication (S230).

In more detail, the second BMS 112 may forward information (SOC, SOH, temperature, voltage, etc.) of the second battery 111 to the DC converter 120, and the DC converter 120 may forward the information to the first BMS 132. In addition, the first BMS 132 may sum the SOC of the second battery 111 and the SOC of the first battery 131 to determine the total available energy. Further, the VCU 150 may determine the total remaining distance range as described above based on the information possessed by the first BMS 132.

When the second BMS 112 may be configured as a cell management unit (CMU) not to directly output SOC and SOH information, and to only output limited information such as cell type information and rated capacity information, the first BMS 132 may estimate information of the second battery 111, which will be described with reference to FIG. 3.

FIG. 3 is a flowchart illustrating an example of a process of estimating a state of the second battery of the swappable battery unit according to an embodiment of the present disclosure.

Referring to FIG. 3, first, the first BMS 132 may receive the cell type information and the rated capacity information of the second battery 111 from the second BMS 112 via the DC converter 120 (S310).

Thereafter, the first BMS 132 may measure the voltage of the second battery 111 in a no-load state (S320), and estimate the SOC based on the measured voltage (S330). To this end, the first BMS 132 may hold and refer to a table in which an SOC for an open circuit voltage (OCV) may be defined for each piece of cell type information (NCM x/y/z, LFP, etc.). Alternatively, various methods may be applied in estimating the SOH, such as charging the second battery 111 with constant power and using the applied amount of charging power or the amount of voltage increase compared to an application time.

In addition, the first BMS 132 may apply a test current of a preset magnitude to the second battery 111 for a preset time to measure an internal resistance of the second battery 111 (S340), and estimate the SOH based on the measured resistance (S350). To this end, the first BMS 132 may hold and refer to a table in which the SOH for the resistance value may be defined for each piece of cell type information (NCM x/y/z, LFP, etc.).

The first BMS 132 may calculate the available energy of the second battery 111 based on the estimated SOC and SOH and the received rated capacity information (S360).

However, the method described above with reference to FIG. 3 is preferably applied in an environment in which the cell type of the second battery 111 provided in the swappable battery unit 110 may be standardized. A reason therefor may be that application of the SOC-OCV table and the SOH-resistance value table for each cell type, which need to be held by the first BMS 132, may be ensured when standardization may be performed. When the cell type information indicates a cell type not previously defined in the table, the first BMS 132 may notify the VCU 150 of this situation to display a warning message.

Returning to FIG. 2 again, as the switch 170 and the main relay 180 may be closed (S240), the power of the first battery 131 may be transferred to the driving power unit 140, and the VCU 150 may determine whether the first battery may be charged in consideration of the state (SOC and temperature) and the load (including driving energy and electric field energy) of the first battery 131 (S250).

For example, when the temperature of the first battery 131 may be within a preset threshold temperature and a current SOC may be lower than a preset upper limit of the SOC, the VCU 150 may determine that the first battery 131 may be charged (Yes in S250).

When it may be determined that the first battery 131 cannot be charged since the current SOC may be high (No in S250), the VCU 150 may wait until the SOC of the first battery 131 may be decreased by a certain amount (ΔSOC) (S260).

Thereafter, the VCU 150 may determine whether the second battery 111 may be in a dischargeable state, for example, whether the SOC of the second battery 111 may be greater than the preset lower limit of the SOC (S270). When it may be determined that the second battery 111 may be discharged (Yes in S270), the VCU 150 forwards a charging command to the first BMS 132. As the charging command may be forwarded to the second BMS 112 via the DC converter 120 again from the first BMS 132, charging control for charging the first battery 131 with the power of the second battery 111 may be performed (S280).

A charging control (S280) process may include temperature-based charging map control 280A and temperature/vehicle speed-based cooling map control 280B.

The temperature-based charging map control 280A may mean that the second BMS 112 controls discharging of the second battery 111 with reference to a charging map in which charging power or current according to the temperature of the second battery 111 may be defined. For example, the charging map may have a form shown in the following Table 2.

TABLE 2

| | . . . | | | | | | . . . |
|---|---|---|---|---|---|---|---|
| | (Lower | | | | | | (Upper |
| | limit of | | | | | | limit of |
| Temperature | charging | | | Room | | | charging |
| (° C.) | temperature) | A-10 | A-5 | temperature (A) | A + 5 | A + 10 | temperature) |
| Charging power | a | b | c | D | e | f | g |
| (kW) | | | | | | | |
| (or current(A)) | | | | | | | |

| | | | |
|---|---|---|---|
| Cut-off voltage | Y | X | Z |
| (V) | | | |

Referring to Table 2, the charging map may have a form in which charging power or charging current may be defined along with a cut-off voltage according to a plurality of temperature ranges. However, it may be apparent to those skilled in the art that this charging map may be an example and that various modifications may be possible.

Next, the temperature/vehicle speed-based cooling map control 280B may mean controlling a cooling means according to a cooling scheme of the swappable battery unit 110. For example, when the swappable battery unit 110 has a cooling fan as the cooling means, the second BMS 112 may control the cooling fan with reference to a cooling map shown in the following Table 3.

TABLE 3

| | | | | |
|---|---|---|---|---|
| Vehicle speed | A | A + 5 | A + 10 | A + . . . |
| Temperature ° C. | | | | (~maximum speed) |
| Minimum cooling | X | X + y | X + y1 | X + y2 |
| start temperature | | | | |
| T + 5 | X1 | X1 + y′ | X1 + y1′ | X1 + y2′ |
| T + 10 | X2 | X2 + y″ | X1 + y1″ | X1 + y2″ |
| T + . . . | X3 | X2 + z | X1 + z1 | X1 + z2 |
| (~maximum battery | | | | |
| temperature) | | | | |

Referring to Table 3, the cooling map may have a form in which the number of operating stages or duty of the cooling fan may be defined according to a plurality of temperature ranges and vehicle speed ranges. However, it may be apparent to those skilled in the art that this cooling map may be an example and that various modifications may be possible.

The charging control (S280) process may continue until the SOC of the first battery 131 reaches a target SOC (No in S290), while the second battery 111 may be discharged (Yes in S270). In other words, when the SOC of the first battery 131 reaches the target SOC (Yes in S290), or when discharging of the second battery 111 becomes impossible (No in S270), the charging control (S280) process may be terminated.

Here, the target SOC may be set using various schemes. As an example, the target SOC may refer to full charge (that is, SOC 100%) or may refer to an upper limit of the SOC preset in the first BMS 132 (BMS SOC upper limit). As another example, when path information may be acquired by the VCU 150, and when a total (or round-trip) path length may be longer than the total remaining distance range on the assumption that all the energy of the first battery 131 and the second battery 111 has been used, the target SOC may be determined based on energy required to arrive at a charging reservation (location) point or a chargeable (location) point. As another example, a lower limit of the SOC of the first battery 131 that may be emotional for each user (that is, an SOC causing an anxious feeling due to a decrease in SOC) may be additionally considered in setting the target SOC.

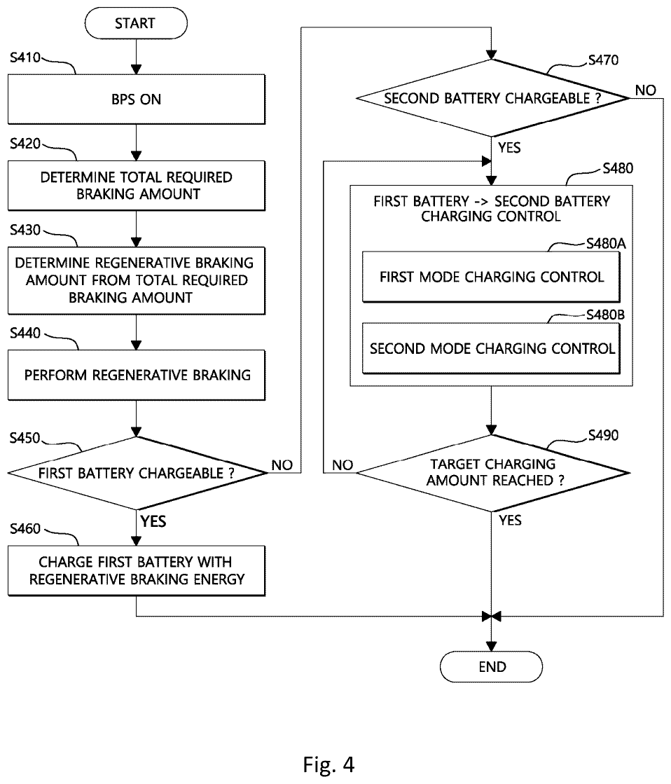

Hereinafter, a power source management method during regenerative braking will be described with reference to FIG. 4.

FIG. 4 is a flowchart illustrating an example of the power source management method during regenerative braking of the electrified vehicle according to an embodiment of the present disclosure.

Referring to FIG. 4, as the brake pedal may be operated (BPS on) (S410), the VCU 150 may determine the total required braking amount based on a BPS value (S420).

An integrated braking controller (for example, Integrated Brake Actuation Unit (iBAU), not illustrated) may determine the friction braking amount to be executed by a hydraulic brake system (not illustrated) and the regenerative braking amount to be executed by the motor of the driving power unit 140 from the total required braking amount (S430), and the inverter may control the reverse torque to be applied from the motor according to the determined regenerative braking amount to perform regenerative braking (S440).

In this instance, the VCU 150 may determine whether the first battery 131 may be in a chargeable state (S450), and when the first battery 131 may be in the chargeable state (Yes in S450), the VCU 150 may control the first BMS 132 so that the first battery 131 may be charged with regenerative braking energy (S460).

On the other hand, when the first battery 131 cannot be charged (No in S450) due to a state in which the current SOC of the first battery 131 reaches the upper limit of the SOC, the VCU 150 may determine whether the second battery 111 may be charged (S470). For example, when the SOC of the second battery 111 may be less than the preset upper limit of the SOC, the VCU 150 may determine that the second battery 111 may be charged.

When the second battery 111 may be charged (Yes in S470), the VCU 150 may forward the charging command to the first BMS 132 to charge the second battery 111 with the power of the first battery 131, so that charging control inducing discharging of the first battery 131 may be performed (S480).

A charging control process (S480) may include a first mode charging control S480A and a second mode charging control S480B.

The first mode charging control S480A may mean a mode in which the first BMS 132 monitors the regenerative charge amount (energy) and charges the second battery 111 in response to the regenerative charge amount.

Next, the second mode charging control S480B may be a mode in which an additional regenerative braking margin resulting from reaching the upper limit of the SOC of the first battery 131 may be considered in advance, and may be particularly effective when the path information may be obtained by the VCU 150. Specifically, the VCU 150 predicts the regenerative braking amount on a forward path over a certain distance based on the path information, and compares the regenerative braking amount with path loss in charging the second battery 111 with the predicted regenerative braking amount. As a result of comparison, when the path loss may be greater, the required braking amount may be executed through friction braking without performing regenerative braking, and when the regenerative braking amount may be greater than the path loss, such as in a high-altitude and long-steel plate situation, it may be possible to perform a control operation so that the second battery 111 may be charged with the power of the first battery 131.

When the target charging amount may be reached through the charging control process (S480) (Yes of S490), the charging control process may be terminated. Here, the target charging amount may correspond to a preset SOC or may be variably set according to the predicted regenerative braking amount depending on the path, which may be an example, and it may be obvious to those skilled in the art that various settings may be possible.

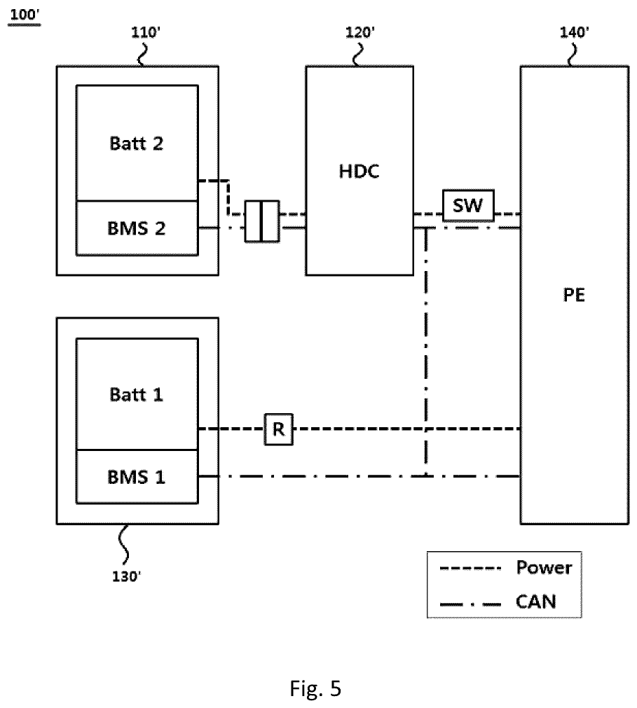

In the embodiment described so far, the swappable battery unit 110 may be connected to the main battery unit 130 via the DC converter 120. That is, the energy of the second battery 111 may be indirectly transferred to the driving power unit 140 in a manner of charging the first battery 131. Alternatively, according to another embodiment of the present disclosure, the DC converter may be directly connected to the driving power unit instead of the main battery unit, which will be described with reference to FIG. 5.

FIG. 5 is a block diagram illustrating an example of an electrified vehicle equipped with a swappable battery according to another embodiment of the present disclosure.

Referring to FIG. 5, a mode in which the main battery unit 130′ may be connected to the driving power unit 140′ and a mode in which the swappable battery unit 110′ may be connected to the DC converter 120′ may be similar to those of FIG. 1. However, the DC converter 120′ may be connected to the driving power unit 140′ rather than the main battery unit 130′. Illustration of remaining elements, such as a VCU, is omitted for clarity of understanding.

In this case, energy of the swappable battery unit 110′ may be directly transferred to the driving power unit 140′ instead of being supplied to the main battery unit 130′.

Accordingly, in comprehensive management of battery energy, the VCU (not illustrated) may sequentially change the energy source so that energy of the main battery unit 130′ may be used first, and energy of the swappable battery unit 110′ may be used after the energy of the main battery unit 130′ may be exhausted. Alternatively, the VCU may use the energy of the main battery unit 130′ and the energy of the swappable battery unit 110′ at the same time or selectively depending on the situation/efficiency.

As an example, when the states of the main battery unit 130′ and the swappable battery unit 110′ may be both within the normal range, energy may be supplied from one side, which may be relatively advantageous for high-load driving, during high-load driving, and energy may be supplied from the other side during low-load driving. Here, in general, a side having a higher capacity and a higher voltage may be advantageous for high-load driving. However, the present disclosure may not be limited thereto.

As another example, when the state of one of the main battery unit 130′ and the swappable battery unit 110′ may be abnormal, energy may be supplied from a battery unit in a normal state.

As another example, the VCU may be configured to determine an assigned output of each battery unit depending on the overall system efficiency in consideration of the driving load and the state of each battery unit, so that the two battery units simultaneously output energy. That is, a battery unit having a higher voltage or SOC may output higher energy. Specifically, assuming the case where the voltage of the main battery unit 130′ may be 750 V and the SOC thereof may be 80% (that is, available energy may be 60 kWh), and the voltage of the swappable battery unit 110′ may be 350 V and the SOC thereof may be 90% (that is, available energy may be 30 kWh), an output ratio may be 4:1 to 2:1 depending on the expected system efficiency, and an allocated output may be variably controlled in consideration of the temperature/SOC/voltage state of each battery unit.

It may be obvious that the case of regenerative braking may be determined similarly to the case of discharging described above (for example, replacing the driving load with the required braking force or the required regenerative braking force).

According to the various embodiments of the present disclosure described above, it may be possible to prevent unnecessary increase in vehicle price or weight by allowing the swappable battery to be additionally mounted in addition to the main battery.

In addition, it may be possible to acquire the state of the mounted swappable battery using various schemes and to perform comprehensive management with the energy of the main battery.

The effects obtainable in the present disclosure may not be limited to the above-mentioned effects, and other effects not mentioned herein may be clearly understood by those of ordinary skill in the art to which the present disclosure belongs from the above description.

The present disclosure described above may be implemented as computer-readable code on a medium in which a program may be recorded. The computer-readable medium includes all types of recording devices in which data readable by a computer system may be stored. Examples of the computer-readable medium include a hard disk drive (HDD), a solid-state drive (SSD), a silicon disk drive (SDD), a ROM, a RAM, a CD-ROM, a magnetic tape, a floppy disk, an optical data storage device, etc. Therefore, the above detailed description should not be construed as restrictive and should be considered as illustrative in all respects. The scope of the present disclosure should be determined by a reasonable interpretation of the appended claims, and all modifications within the equivalent scope of the present disclosure may be included in the scope of the present disclosure.

1.-19. (canceled)

20. A vehicle comprising:
a motor configured to supply a driving force for the vehicle;
a first battery configured to supply first power to the motor, the first battery comprising first battery cells of a first cell type;
a second battery configured to supply second power to the motor, the second battery comprising second battery cells of a second cell type; and
a controller configured to control the supply of the power from the first battery or the second battery.

21. The vehicle of claim 20, wherein the first cell type comprises a cell type of a lithium iron phosphate (LFP) cathode.

22. The vehicle of claim 21, wherein the second type comprises a cell type of a Li-ion cathode comprising nickel.

23. The vehicle of claim 20, wherein a first energy capacity of the first battery is different from a second energy capacity of the second battery.

24. The vehicle of claim 22, wherein the first energy capacity is less than half of the second energy capacity.

25. The vehicle of claim 20, wherein a first voltage of the first battery is different from a second voltage of the second battery.

26. The vehicle of claim 24, wherein the first voltage is higher than the second voltage.

27. The vehicle of claim 20, wherein the controller is further configured to sequentially supply the first power and the second power to the motor.

28. The vehicle of claim 26, wherein the controller is further configured to supply the second power to the motor when an energy level of the first battery reaches a preset level.

29. The vehicle of claim 20, wherein the controller is further configured to supply the first power or the second power to the motor based on a driving situation.

30. The vehicle of claim 28, wherein the controller is further configured to supply the first power or the second power to the motor based on a driving load.

31. The vehicle of claim 29, wherein the controller is further configured to supply power from a battery with a lower energy capacity between the first battery and the second battery during a low-load driving situation based on the driving load.

32. The vehicle of claim 30, wherein the controller is further configured to supply power from a battery with a higher energy capacity between the first battery and the second battery during a high-load driving situation based on the driving load.

33. The vehicle of claim 28, wherein the controller is further configured to supply both the first power and the second power to the motor based on a driving load.

34. The vehicle of claim 32, wherein the controller is further configured to determine an assigned output power of each of the first battery and the second battery based on an efficiency for the driving load.

35. The vehicle of claim 20, further comprising a DC-DC converter configured to convert voltage between the first battery and the second battery.

36. The vehicle of claim 34, wherein the controller is further configured to control the DC-DC converter to charge the first battery using the second power.

37. The vehicle of claim 35, wherein the DC-DC converter comprises a boost converter.

38. The vehicle of claim 35, wherein the controller is further configured to determine the charging based on a state of charge (SOC) or a temperature of the first battery.

39. The vehicle of claim 20, wherein the controller is further configured to determine an abnormal state in either the first battery or the second battery and supply power from the other battery to the motor.
